(19) United States
(12) Patent Application Publication
(10) Pub. No.: US 2010/0102341 A1
(43) Pub. Date: Apr. 29, 2010

(54) SEMICONDUCTOR LIGHT EMITTING DEVICE AND METHOD FOR MANUFACTURING THE SAME

(75) Inventors: Kazuaki Tsutsumi, Kyoto (JP); Yohei Ito, Kyoto (JP); Yasuo Nakanishi, Kyoto (JP); Shunji Nakata, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-shi, Kyoto-fu (JP)

(21) Appl. No.: 12/452,049

(22) PCT Filed: Jun. 3, 2008
(86) PCT No.: PCT/JP2008/060209

§ 371 Date: Dec. 14, 2009

(30) Foreign Application Priority Data
Jun. 15, 2007 (JP) 2007-158569
Jun. 15, 2007 (JP) 2007-159095
Nov. 8, 2007 (JP) 2007-290618

(51) Int. Cl. H01L 33/00; H01L 21/302

(52) U.S. Cl. 257/98; 438/33; 257/E33.074; 257/E21.214

(57) ABSTRACT

A semiconductor light emitting device includes: a transparent substrate including a first principal surface and a second principal surface opposite with the first principal surface, in which side surfaces between the first principal surface and the second principal surface are rough surfaces; and a semiconductor light emitting element that is arranged on the first principal surface of the transparent substrate and is composed by stacking nitride semiconductors on each other.

### TECHNICAL FIELD

The present invention relates to a semiconductor light emitting device, and particularly relates to a semiconductor light emitting device including a semiconductor light emitting element formed on a wafer of a nitride semiconductor, and to a method for manufacturing the semiconductor light emitting device.

### BACKGROUND ART

A semiconductor light emitting device made of group III nitride semiconductors is used for a light emitting diode (LED) and the like. As examples of the group III nitride semiconductors, there are aluminum nitride (AlN), gallium nitride (GaN), indium nitride (InN) and the like. Typical group III nitride semiconductors are represented by AlₓIn_{y}Ga_{1-x-y}N (0≦x≦1, 0≦y≦1, 0≦x+y≦1). The semiconductor light emitting device using the group III nitride semiconductors includes, for example, a semiconductor light emitting element having a structure in which a group III nitride semiconductor layer (n-type semiconductor layer) doped with an N-type dopant, a light emitting layer (active layer) and a group III nitride semiconductor layer (p-type semiconductor layer) doped with a p-type dopant are stacked on one another in this order, and the like.

The nitride semiconductor layers are stacked on a wafer as a transparent substrate, which is made of sapphire and the like, whereby a plurality of the semiconductor light emitting devices is formed on the wafer. After a manufacturing process in a state of the wafer is finished, the wafer is divided into a plurality of chips, and the semiconductor light emitting devices are manufactured, in each of which the nitride semiconductors are stacked on the transparent substrate.

Heretofore, in the case of dividing the wafer into the plurality of chips, a back surface of the wafer has been polished to thereby thin a thickness of the wafer concerned from 350 μm to approximately 100 μm, and thereafter, scribe lines have been formed on a front surface of the wafer, on which the nitride semiconductors are formed, by means of a diamond cutter and the like. Then, an impact has been applied to the scribe lines from the back surface, and the wafer has been divided into the chips by “break” (for example, refer to Patent Citation 1). Here, the “break” refers to the division of the wafer into the plurality of chips by performing breaking (fracture), cutting and the like therefor.
[Patent Citation 1] Japanese Patent No. 3449201

### DISCLOSURE OF INVENTION

### Technical Problem

However, in the case of breaking the wafer into the chips, which contain the nitride semiconductors formed on the transparent substrate, after the subscribe lines are formed on the front surface of the wafer made of the sapphire and the like, then side surfaces (cut surfaces) of the transparent substrate become mirror surfaces. Therefore, there has been a problem that light that is generated in the active layer of the semiconductor light emitting element formed on the transparent substrate and is incident onto the transparent substrate is reflected by the side surfaces of the transparent substrate and has difficulty being outputted to the outside.

Moreover, in the case of forming the scribe lines only on one surface of the hard wafer made of the sapphire and the like and breaking the wafer into the respective chips, then sometimes, directions where the wafer is broken become inconstant depending on a degree of the impact application, and cracks occur in the vicinities of cut parts on the surface on which the scribe lines are not formed. Accordingly, there has occurred a problem that breakage and chipping occur on surfaces of the chips to cause variations in shape of the chips, resulting in lowering of yield of the semiconductor light emitting device.

### Technical Solution

In consideration of the above-described problems, the present invention provides a semiconductor light emitting device capable of efficiently outputting, to the outside of the transparent substrate, the light incident onto the transparent substrate from the semiconductor light emitting element on the transparent substrate, and of suppressing the occurrence of the cracks on the cut parts in the case of dividing the wafer into the chips, and provides a method for manufacturing the semiconductor light emitting device.

In accordance with an aspect of the present invention, a semiconductor light emitting device is provided, which includes: a transparent substrate including a first principal surface and a second principal surface opposite with the first principal surface, in which side surfaces between the first principal surface and the second principal surface are rough surfaces; and a semiconductor light emitting element that is arranged on the first principal surface of the transparent substrate and is composed by stacking nitride semiconductors on each other.

In accordance with another aspect of the present invention, there is provided a method for manufacturing a semiconductor light emitting device, in which a wafer that is made of sapphire and includes a first principal surface and a second principal surface opposite with the first principal surface, the first principal surface having a nitride semiconductor layer formed thereon, is divided into a plurality of chips, the method including: preparing a cutting apparatus; pasting the wafer onto an adhesive tape; and cutting the wafer from one of the first principal surface and the second principal surface to the other by means of the cutting apparatus until the wafer is divided into the plurality of chips.

### Advantageous Effects

In accordance with the present invention, there can be provided the semiconductor light emitting device capable of efficiently outputting, to the outside of the transparent substrate, the light incident onto the transparent substrate from the semiconductor light emitting element on the transparent substrate, and of suppressing the occurrence of the cracks on the cut parts in the case of dividing the wafer into the chips, and be provided the method for manufacturing the semiconductor light emitting device.

### BRIEF DESCRIPTION OF DRAWINGS

FIG. 1 is a schematic view showing a configuration example of a semiconductor light emitting device according to a first embodiment of the present invention.

FIG. 2 is a perspective view showing the semiconductor light emitting device according to the first embodiment of the present invention.

FIG. 3 is a schematic view showing a configuration example of an active layer of the semiconductor light emitting device according to the first embodiment of the present invention.

FIG. 4 is a gas flow pattern diagram in crystal growth of the active layer of the semiconductor light emitting device according to the first embodiment of the present invention.

FIGS. 5(a) to 5(c) are process cross-sectional views for explaining an example of a method for manufacturing the semiconductor light emitting device according to the first embodiment of the present invention.

FIGS. 6(a) to 6(d) are process cross-sectional views for explaining another example of the method for manufacturing the semiconductor light emitting device according to the first embodiment of the present invention.

FIGS. 7(a) to 7(d) are process cross-sectional views for explaining still another example of the method for manufacturing the semiconductor light emitting device according to the first embodiment of the present invention.

FIG. 8 is a schematic view showing a configuration example of the semiconductor light emitting device according to the first embodiment of the present invention.

FIG. 9 is a schematic view showing a configuration example of the semiconductor light emitting device according to the first embodiment of the present invention.

FIG. 10 is a schematic view showing a configuration example of the semiconductor light emitting device according to the first embodiment of the present invention.

FIG. 11 is a schematic view showing a configuration example of the semiconductor light emitting device according to the first embodiment of the present invention.

FIG. 12 is a table showing characteristics of semiconductor light emitting devices manufactured by the method for manufacturing the semiconductor light emitting device according to the first embodiment of the present invention and by the related art.

FIG. 13 is a graph showing the characteristics of the semiconductor light emitting devices manufactured by the method for manufacturing the semiconductor light emitting device according to the first embodiment of the present invention and by a manufacturing method of the related art.

FIGS. 14(a) and 14(b) are image data of a cut section of a substrate manufactured by the method for manufacturing the semiconductor light emitting device according to the first embodiment of the present invention.

FIGS. 15(a) and 15(b) are image data of a cut section of a substrate manufactured by the manufacturing method of the related art.

FIG. 16 is image data of a cut section of a substrate manufactured by the method for manufacturing the semiconductor light emitting device according to the first embodiment of the present invention.

FIG. 17 is image data of a cut section of a substrate manufactured by the method for manufacturing the semiconductor light emitting device according to the first embodiment of the present invention.

FIGS. 18(a) to 18(c) are process cross-sectional views for explaining an example of a method for manufacturing a semiconductor light emitting device according to a second embodiment of the present invention.

FIG. 19 is a schematic view for explaining a beam width of a laser for use in the method for manufacturing a semiconductor light emitting device according to the second embodiment of the present invention.

FIG. 20 is a table showing relationships between defocus values and kerf widths.

FIG. 21 is image data of a cut section of a chip manufactured by the method for manufacturing a semiconductor light emitting device according to the second embodiment of the present invention.

FIG. 22 is image data of a cut section of a chip manufactured by the manufacturing method of the related art.

FIGS. 23(a) to 23(c) are process cross-sectional views for explaining another example of the method for manufacturing a semiconductor light emitting device according to the second embodiment of the present invention.

### BEST MODE FOR CARRYING OUT THE INVENTION

Next, a description will be made of first and second embodiments of the present invention with reference to the drawings. In the following description referring to the drawings, the same or similar reference numerals are assigned to the same or similar portions. However, the drawings are schematic, and it should be noted that relationships between thicknesses and planar dimensions, a ratio of thicknesses of the respective layers, and the like are different from the actual ones. Hence, specific thicknesses and dimensions should be determined in consideration of the following description. Moreover, it is a matter of course that the respective drawings also include portions different from one another in dimensional relationship and ratio.

Moreover, the first and second embodiments, which will be described below, illustrate a device and method for embodying the technical idea of this invention, and the technical idea of this invention does not limit materials, shapes, structures, arrangements and the like of constituent components to the following ones. The technical idea of this invention can be modified in various ways within the scope of claims.

### First Embodiment

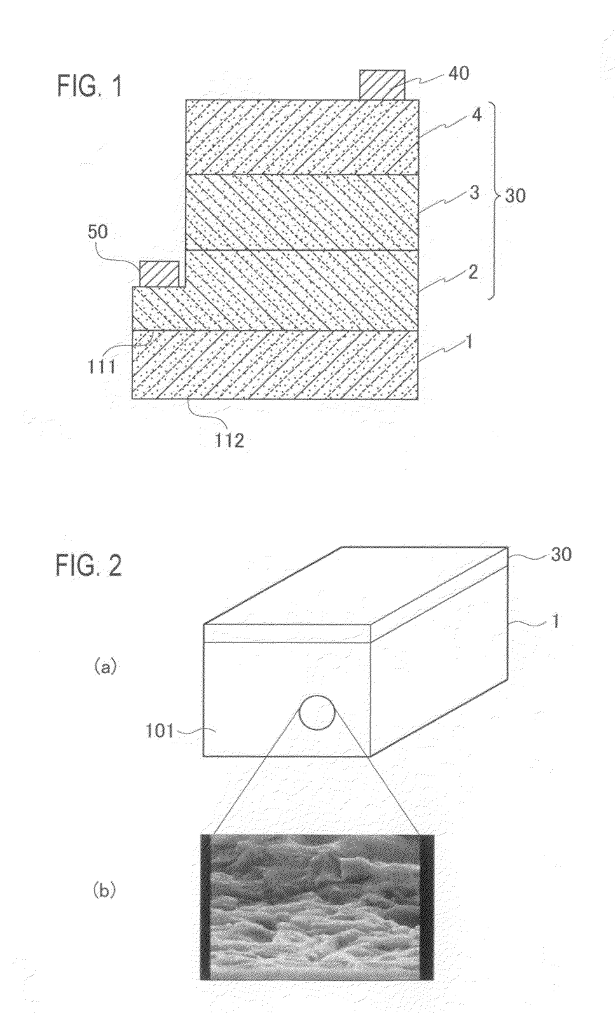

As shown in FIG. 1, a semiconductor light emitting device according to the first embodiment of the present invention includes: a transparent substrate 1 having a first principal surface 111 and a second principal surface 112 opposite with the first principal surface 111, in which side surfaces between the first principal surface 111 and the second principal surface 112 are rough surfaces; and a semiconductor light emitting element that is arranged on the first principal surface 111 of the transparent substrate 1, and includes a nitride semiconductor layer 30 composed by stacking nitride semiconductors on one another. As shown in FIG. 2(a) and FIG. 2(b), a side surface 101 among the side surfaces of the transparent substrate 1 is the rough surface because of irregularities caused by a dicing process for cutting and dividing a wafer into chips as will be described later. FIG. 2(a) is a perspective view of the semiconductor light emitting device shown in FIG. 1, and FIG. 2(b) is an SEM photograph in which the side surface 101 of the transparent substrate 1 is enlarged (magnification: approximately 6000 times).

The nitride semiconductor layer 30 shown in FIG. 1 is a semiconductor light emitting element including: an n-type semiconductor layer 2 doped with an n-type dopant; an active layer 3 arranged on the n-type semiconductor layer; and a p-type semiconductor layer 4 arranged on the active layer 3.

For example, a substrate made of a nitride semiconductor, and the like are adoptable as the transparent substrate 1. Specifically, a sapphire substrate is usable as the transparent substrate 1. A thickness of the transparent substrate 1 ranges approximately from 40 μm to 700 μm, and preferably, is approximately 350 μm.

Group III nitride semiconductors are adoptable for the n-type semiconductor layer 2, the active layer 3 and the p-type semiconductor layer 4. The n-type semiconductor layer 2 supplies electrons to the active layer 3, and the p-type semiconductor layer 4 supplies holes to the active layer 3. The supplied electrons and holes are recombined with each other in the active layer 3, whereby light is generated.

As the n-type semiconductor layer 2, for example, a GaN layer or the like is adoptable, which is made of a group III nitride semiconductor doped with silicon (Si) or the like as the n-type dopant and having a film thickness ranging approximately from 0.2 to 5 μm. As the p-type semiconductor layer 4, for example, a GaN layer or the like is adoptable, which is made of a group III nitride semiconductor doped with the p-type dopant and having a film thickness ranging approximately from 0.05 to 1 μm. As the p-type dopant, usable are magnesium (Mg), zinc (Zn), cadmium (Cd), calcium (Ca), beryllium (Be), carbon (C) and the like.

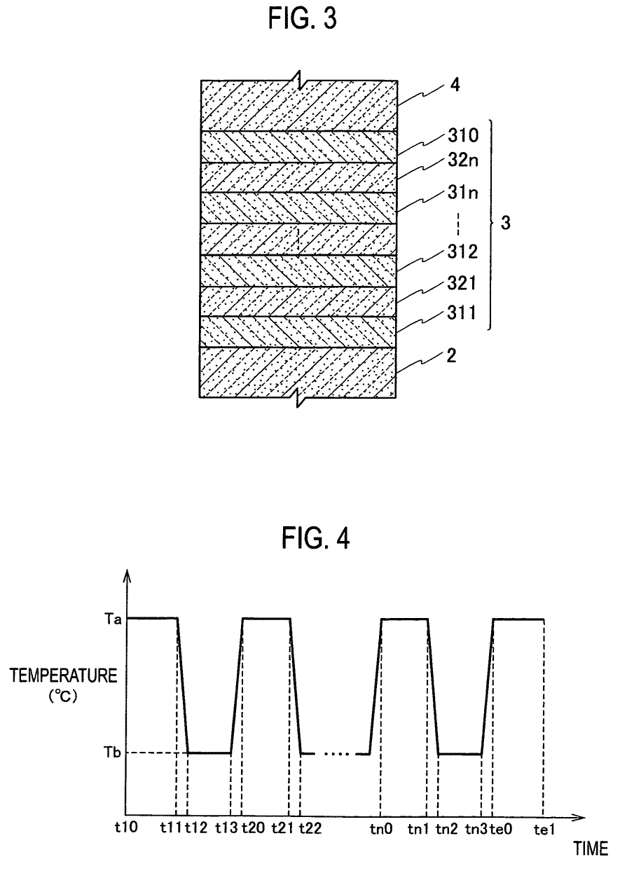

The active layer 3 has a quantum well structure in which a well layer 32 is sandwiched by barrier layers 31 of which bang gap is larger than that of the well layer 32. Moreover, the active layer 3 may adopt a multiple quantum well (MQW) structure in which the quantum well structure having the well layer sandwiched by the barrier layers is taken as a unit structure, and this unit structure is stacked n times (n: integer of two or more). In the case of adopting the MQW structure, for example as shown in FIG. 3, the active layer 3 includes a first well layer 321 to an n-th well layer 32n, which are individually sandwiched by a first barrier layer 311 to an n-th barrier layer 31n and a final barrier layer 310. Specifically, the first well layer 321 is arranged between the first barrier layer 311 and the second barrier layer 312, and the second well layer (not shown) is arranged between the second barrier layer 312 and the third barrier layer (not shown). Moreover, the n-th well layer 32n is arranged between the n-th barrier layer 31n and the final barrier layer 310. The first barrier layer 311 of the active layer 3 is arranged on the n-type semiconductor layer 2, and the p-type semiconductor layer 4 is arranged on the final barrier layer 310 of the active layer 3.

Hereinafter, the first barrier layer 311 to the n-th barrier layer 31n and the final barrier layer 310, which are included in the active layer 3 in the case of the MQW structure, will be collectivly referred to as “barrier layers 31”. Moreover, all the well layers included in the active layer 3 will be hereinafter referred to as “well layers 32”. The barrier layers 31 are formed, for example, of GaN films, and the well layers 32 are formed, for example, of indium gallium nitride (InGaN) films. Note that a composition ratio of the indium (In) in the well layers 32 is appropriately set in response to a wavelength of light desired to be generated. Moreover, InGaN films in which a composition ratio of In is smaller than in the well layers 32 may be adopted as the barrier layers 31.

The semiconductor light emitting device shown in FIG. 1 further includes: an n-side electrode 50 that applies a voltage to the n-type semiconductor layer 2; and a p-side electrode 40 that applies a voltage to the p-type semiconductor layer 4. As shown in FIG. 1, the n-side electrode 50 is arranged on a surface of the n-type semiconductor layer 2, which is exposed by mesa-etching partial regions of the p-type semiconductor layer 4, the active layer 3 and the n-type semiconductor layer 2. The p-side electrode 40 is arranged on the p-type semiconductor layer 4. The n-side electrode 50 is formed, for example, of an aluminum (Al) film, and the p-side electrode 40 is formed, for example, of a titanium (Ti) film, a nickel (Ni) film, a transparent electrode such as an indium tin oxide (ITO) film and a zinc oxide (ZnO) film, or a palladium (Pd)-gold (Au) alloy film. Moreover, the n-side electrode 50 and the p-side electrode 40 are ohmically connected to the n-type semiconductor layer 2 and the p-type semiconductor layer 4, respectively.

A description will be made below of an example of a method for manufacturing the semiconductor light emitting device shown in FIG. 1. Note that the method for manufacturing the semiconductor light emitting device, which will be described below, is merely an example, and it is a matter of course that the semiconductor light emitting device is realizable by other various manufacturing methods including modification examples of the method example that will be described below.

In the manufacturing method, GaN is grown on the transparent substrate 1 by the well-known metalorganic chemical vapor deposition (MOCVD) method and the like. For example, after the transparent substrate 1 such as a sapphire substrate is thermally cleaned, a GaN film doped with Si at a concentration of approximately 3×10¹⁸ atoms/cm³ is grown as the n-type semiconductor layer 2 to an approximate thickness range of 1 to 5 μm on the transparent substrate 1 with a buffer layer formed, for example, of a GaN film or an AlN film interposed therebetween while setting a substrate temperature at approximately 1000° C. At this time, trimethyl gallium (TMG), ammonia (NH₃) and silane (SH₄) are supplied as raw material gases, whereby the n-type semiconductor layer 2 is formed.

Next, the barrier layers 31 formed, for example, of the GaN films and the well layers 32 formed, for example, of the InGaN films are stacked alternately on one another, and the active layer 3 is formed on the n-type semiconductor layer 2. Specifically, the barrier layers 31 and the well layers 32 are grown alternately and continuously while adjusting the substrate temperature and a flow rate of each raw material gas in the event of forming the active layer 3, and the active layer 3 composed by stacking the barrier layers 31 and the well layers 32 on one another is formed. In the case where the active layer 3 has the MQW structure, a step of stacking the well layer 32 and the barrier layer 31 of which bang gap is larger than that of the well layer 32 on each other by adjusting the substrate temperature and the flow rate of the raw material gas is taken as a unit step, and this unit step is repeated n times, for example, eight times, whereby a stack structure in which the barrier layers 31 and the well layers 32 are alternately stacked is obtained.

FIG. 4 shows an example of stacking the barrier layers 31 and the well layers 32. The barrier layers 31 are formed at a substrate temperature Ta, and the well layers 32 are formed at a substrate temperature Tb. Specifically, the first barrier layer 311 is formed from a time t10 to a time t11, during which the substrate temperature is set at Ta. Subsequently, the substrate temperature is dropped down to Tb from the time t11 to a time t12. Then, from the time t12 to a time t13, the first well layer 321 is formed at the substrate temperature Tb. Thereafter, the substrate temperature is raised up to Ta from the time t13 to a time t20, and the second barrier layer 312 is then formed. Also thereafter, in a similar way, the barrier layers 31 and the well layers 32 are alternately formed at the substrate temperature Ta and the substrate temperature Tb, respectively. Then, the n-th barrier layer 31n is formed from a time tn0 to a time tn1, the substrate temperature is dropped down to Tb from the time tn1 to a time tn2, and the n-th well layer 32n is formed from the time tn2 to a time tn3. Then, the substrate temperature is raised up to Ta from the time tn3 to a time te0, and the final barrier layer 310 is formed from the time te0 to a time tel. In such a way, the active layer 3 is completed. Note that, at each time when the substrate temperature is raised up and at each time when the substrate temperature is dropped down, the barrier layer 31 or the well layer 32 can be grown and discontinued to be grown.

In the case of forming the barrier layers 31, for example, the TMG gas and the NH₃ gas are supplied as the raw material gases to a processing apparatus for deposition. Meanwhile, in the case of forming the well layers 32, for example, the TMG gas, the trimethyl indium (TMI) gas and the NH₃ gas are supplied as the raw material gases to the processing apparatus. Note that the TMG gas is supplied as raw material gas of Ga atoms, the TMI gas is supplied as raw material gas of In atoms, and the NH₃ gas is supplied as raw material gas of nitrogen atoms.

Subsequently, the substrate temperature is set at an approximate range of 800° C. to 1000° C., and the p-type semiconductor layer 4 doped with the p-type dopant is formed to an approximate thickness range of 0.05 to 1 μm on the active layer 3. As the p-type semiconductor layer 4, for example, adoptable is a GaN layer doped, for example, with Mg as the p-type dopant at a concentration of approximately 3×10¹⁹ atoms/cm³, or the like. In the case where the GaN layer is doped with Mg, then the TMG gas, the NH₃ gas and bis (cyclopentadienyl) magnesium (Cp₂Mg) gas are supplied as the raw material gases, whereby the p-type semiconductor layer 4 is formed.

Then, portions from the p-type semiconductor layer 4 to some midpoint of the n-type semiconductor layer 2 are removed by the mesa etching by means of reactive ion etching and the like, and a front surface of the n-type semiconductor layer 2 is exposed. Thereafter, the n-side electrode 50 is formed on the front surface of the exposed n-type semiconductor layer 2 by evaporation, and the p-side electrode 40 is formed on the p-type semiconductor layer 4 by the evaporation, whereby the semiconductor light emitting element of the semiconductor light emitting device shown in FIG. 1 is completed.

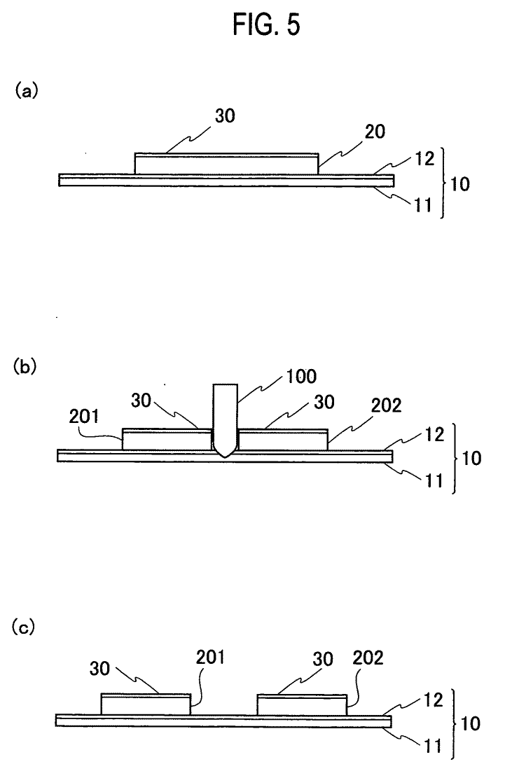

Next, with reference to FIG. 5(a) to FIG. 5(c), a description will be made of a method for manufacturing the semiconductor light emitting device shown in FIG. 1 in such a manner that a wafer 20 on which a plurality of the above-described semiconductor light emitting elements are formed is divided into the chips by using a cutting apparatus. The method for manufacturing the semiconductor light emitting device according to the first embodiment of the present invention, which will be described below, is a method for manufacturing a semiconductor light emitting device in such a manner that the wafer 20, which is made of the sapphire, and has a first principal surface on which the nitride semiconductor layer 30 is formed, and a second principal surface opposite with the first principal surface, is divided into the plurality of chips. The manufacturing method includes: preparing the cutting apparatus; pasting the wafer 20 onto an adhesive tape 10; and cutting the wafer 20 from one of the first principal surface thereof and the second principal surface thereof to the other by means of the cutting apparatus until the wafer 20 is divided into a chip 201 and a chip 202. The manufacturing method shown in FIG. 5(a) to FIG. 5(c) is a dicing process for cutting the wafer 20 from one of the first principal surface and the second principal surface to the other by using, as the cutting apparatus, a dicer including a blade until the wafer 20 is divided into the plurality of chips.

The nitride semiconductor layer 30 shown in FIG. 1 is stacked on the first principal surface of the wafer 20, whereby the semiconductor light emitting element is formed. Here, a description will be illustratively made of the case of cutting the wafer from the first principal surface toward the second principal surface by means of the dicer. Specifically, the dicing process is implemented until the wafer 20 is divided into the chip 201 and the chip 202 while taking the first principal surface as a cutting starting surface and taking the second principal surface as a cutting ending surface, whereby the wafer 20 is cut into a plurality of the semiconductor light emitting devices shown in FIG. 1. Each of the chip 201 and the chip 202 is the semiconductor light emitting device shown in FIG. 1.

First, as shown in FIG. 5(a), the second principal surface of the wafer 20 is pasted onto an adhesive 12 side of the adhesive tape 10 composed by stacking a tape base material 11 and the adhesive 12 on each other.

Next, as shown in FIG. 5(b), by means of a first blade 100 owned by the dicer, the wafer 20 is cut from the first principal surface to the second principal surface until being divided into the chip 201 and the chip 202. Specifically, the wafer 20 is fully cut, and a tip end of the first blade 100 reaches the adhesive tape 10.

Subsequently, as shown in FIG. 5(c), the adhesive tape 10 is expanded, and each of the chip 201 and the chip 202 can be acquired as the semiconductor light emitting device shown in FIG. 1.

For example, a blade thickness of the first blade 100 approximately ranges from 50 to 200 μm. As the first blade 100, resin and metal blades in which a plurality of diamonds is arranged in resin and metal, and the like are adoptable. Although the resin and metal blades are lower in hardness than the sapphire substrate adoptable as the transparent substrate 1, the resin and metal blades can cut the sapphire substrate by setting a particle diameter and concentration ratio (arrangement) of the diamonds. A bond material of the metal blade is metal, and a bond material of the resin blade is thermosetting resin (phenol resin) and the like.

For example, hard polyvinyl chloride (PVC), polyolefin (PO), polyethylene terephthalate (PET) and the like are adoptable as the tape base material 11 of the adhesive tape 10. Moreover, it is preferable that a thickness of the adhesive 12 approximately range from 5 to 10 μm. This is because the wafer 20 pasted onto the adhesive 12 is prone to move if the adhesive 12 is too thick.

In the above, the description has been made of the example of fully cutting the wafer 20 from the first principal surface to the second principal surface by means of the first blade 100; however, it is a matter of course that the wafer 20 may be fully cut from the second principal surface to the first principal surface by means of the first blade 100.

Moreover, though it is necessary to set the thickness of the wafer at approximately 100 μm, for example, 80 μm in the method of breaking the wafer into the respective chips, the wafer 20 can be fully cut even if the thickness thereof is approximately 350 μm in accordance with the method of dividing the wafer, which has been described with reference to FIG. 5(a) to FIG. 5(c). Therefore, the step of thinning the wafer 20 can be omitted. Moreover, since it is unnecessary to apply an impact for breaking the wafer into the chips, a manufacturing process can be shortened.

Next, a description will be made of a dicing process for dividing the wafer 20 into the chips by using, as the cutting apparatus, a dicer including the first blade and a second blade thinner in blade thickness than the first blade. Specifically, while taking one of the first principal surface and second principal surface of the wafer 20 as the cutting starting surface and taking the other as the cutting ending surface, a groove is formed from the cutting starting surface to a midpoint of an inside of the wafer 20 by means of the first blade. Moreover, a groove is formed from the midpoint to the cutting ending surface by means of the second blade until the wafer 20 is divided into the plurality of chips (semiconductor light emitting devices), whereby the wafer 20 is cut.

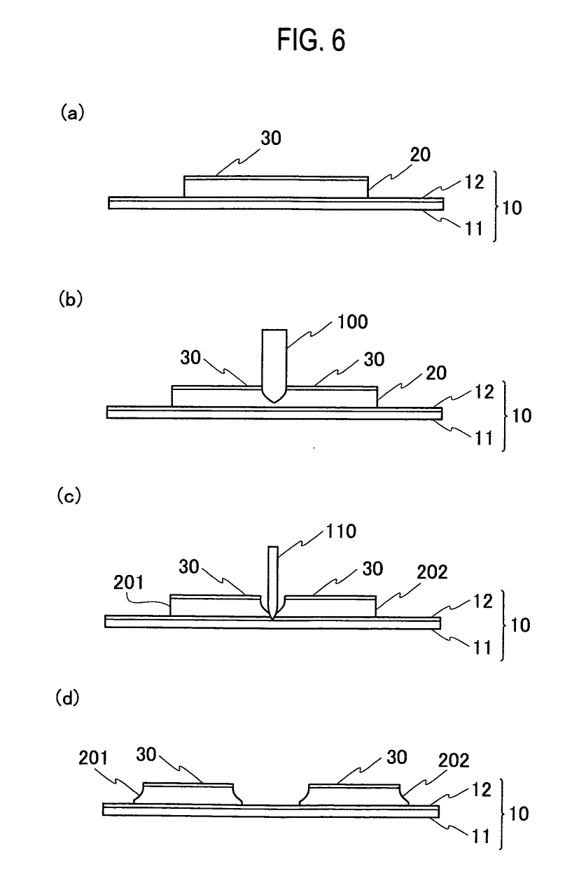

With reference to FIG. 6(a) to FIG. 6(d), a description will be made of details of a wafer cutting method using the dicer including the first blade and the second blade. Here, a description will be made of an example of cutting the wafer 20 from the first principal surface toward the second principal surface. Specifically, the wafer 20 is cut into the plurality of chips while taking the first principal surface as the cutting starting surface and taking the second principal surface as the cutting ending surface.

First, as shown in FIG. 6(a), the second principal surface of the wafer 20 as a subject to be divided, in which the nitride semiconductor layer 30 is formed on the first principal surface, is pasted onto the adhesive 12 side of the adhesive tape 10 composed by stacking the tape base material 11 and the adhesive 12 on each other.

Next, as shown in FIG. 6(b), a groove is formed from the first principal surface to some midpoint of the wafer 20 in a thickness direction by means of the first blade 100.

Subsequently, as shown in FIG. 6(c), by means of the second blade 110 thinner in blade thickness than the first blade 100, a groove is formed to the second principal surface from a bottom portion of the groove of the wafer 20, which is formed by means of the first blade 100, until the wafer 20 is divided into the chip 201 and the chip 202. Specifically, the wafer 20 is fully cut, and a tip end of the second blade 110 reaches the adhesive tape 10.

Subsequently, as shown in FIG. 6(d), the adhesive tape 10 is expanded, and each of the chip 201 and the chip 202 can be acquired as the semiconductor light emitting device shown in FIG. 1.

For example, the blade thickness of the first blade 100 approximately ranges from 50 to 200 μm. For example, a blade thickness of the second blade 110 approximately ranges from 20 to 100 μm, and this blade thickness is selected as a thinner one than that of the first blade 100. As each of the first blade 100 and the second blade 110, resin and metal blades in which a plurality of diamonds is arranged in resin and metal, and the like are adoptable.

For the purpose of performing a final stage of fully cutting the wafer 20 by means of the second blade 110, as shown in FIG. 6(c), side surfaces of the groove formed in the wafer 20 do not contact the second blade 110 at the point of time when the second blade 110 reaches the second principal surface. Therefore, it is possible to acquire chips having less chipping and a satisfactory shape. In the case where the thickness of the wafer 20 is approximately 350 μm, for example, preferably, a groove having a depth of approximately 300 μm is formed by means of the first blade 100, and the wafer 20 is further cut along the groove by approximately 50 μm as the rest of the entire thickness by means of the second blade 110, whereby the wafer 20 is cut apart.

As shown in FIG. 6(d), cut sections of the chip 201 and the chip 202 in a direction perpendicular to the first principal surface of the transparent substrate 1 have a taper shape, and the taper shape depends on a shape of the tip end portion of the first blade 100. For example, in the case where an inclination of the taper shape is desired to be steepened, a sectional shape of the tip end portion of the first blade 100 is allowed to have a small radius or a V shape, and in the case where the inclination of the taper shape is desired to be moderated, the sectional shape of the tip end portion of the first blade 100 is allowed to have a large radius.

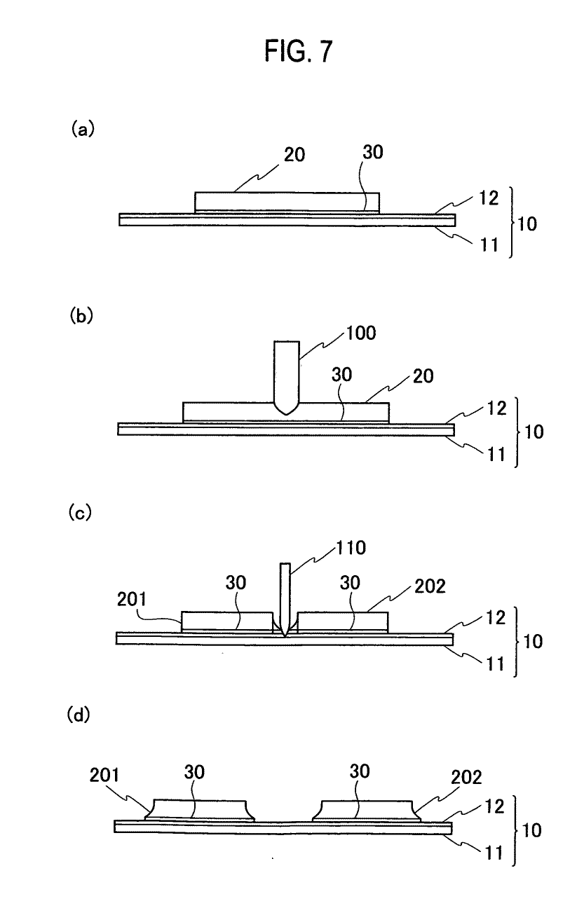

In the above, the description has been made of the example of fully cutting the wafer 20 from the first principal surface to the second principal surface by means of the first blade 100 and the second blade 110; however, it is a matter of course that the wafer 20 may be fully cut from the second principal surface to the first principal surface. FIGS. 7(a) to 7(d) show an example of cutting the wafer 20 from the second principal surface to the first principal surface while taking the second principal surface as the cutting starting surface and taking the first principal surface as the cutting ending surface.

First, as shown in FIG. 7(a), the first principal surface on which the nitride semiconductor layer 30 is formed is pasted onto the adhesive 12 side of the adhesive tape 10 composed by stacking the tape base material 11 and the adhesive 12 on each other.

Next, as shown in FIG. 7(b), a groove is formed from the second principal surface to some midpoint of the wafer 20 in the thickness direction by means of the first blade 100.

Subsequently, as shown in FIG. 7(c), by means of the second blade 110 thinner in blade thickness than the first blade 100, a groove is formed to the first principal surface from a bottom portion of the groove of the wafer 20, which is formed by means of the first blade 100, until the wafer 20 is divided into the chip 201 and the chip 202.

Subsequently, as shown in FIG. 7(d), the adhesive tape 10 is expanded, and each of the chip 201 and the chip 202 can be acquired as the semiconductor light emitting device.

In accordance with the wafer cutting method described above, the wafer 20 can be divided by being fully cut. Therefore, unlike the method of breaking the wafer into the respective chips after forming scribe lines, an occurrence of cracks in the vicinities of cut parts can be suppressed, and shapes of chip surfaces do not vary. Accordingly, yield of the semiconductor light emitting device can be enhanced. Moreover, two blades different in blade thickness from each other are used, whereby chips having a satisfactory shape, in which the chipping is suppressed, can be acquired.

Also by each of the methods described with reference to FIG. 6(a) to FIG. 6(d) and FIG. 7(a) to FIG. 7(d), the wafer is fully cut by means of the dicer, and accordingly, the side surfaces of the transparent substrate 1 become rough surfaces as shown in FIG. 2(b) because of the irregularities caused by cutting the wafer 20 in the dicing process. Therefore, light incident onto the transparent substrate 1 from the active layer 3 of the semiconductor light emitting element is not reflected by the side surfaces of the transparent substrate 1, but becomes likely to be outputted to the outside from the transparent substrate, whereby output efficiency of the semiconductor light emitting device can be improved.

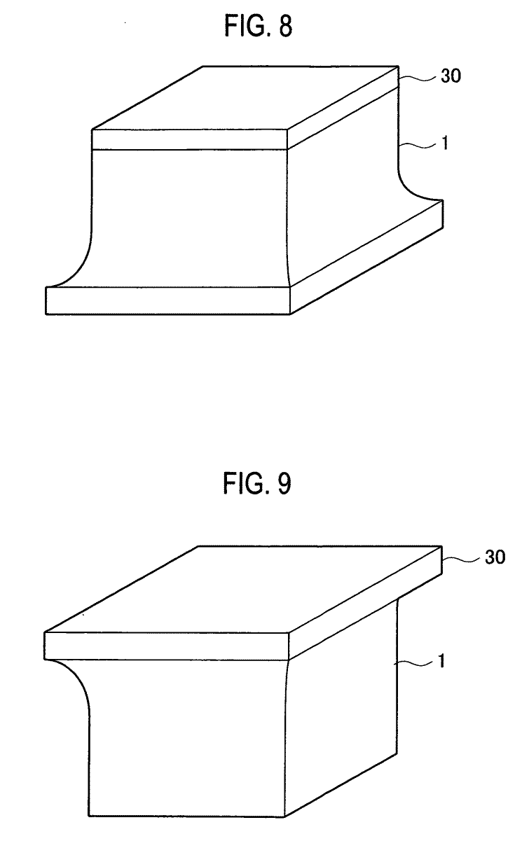

As already mentioned, the side surfaces of the semiconductor light emitting device have the taper shape by depending on the shape of the tip end portion of the first blade 100, and the like. FIG. 8 shows an example of the semiconductor light emitting device manufactured by the method described with reference to FIG. 6(a) to FIG. 6(d), that is, while taking the first principal surface of the wafer 20 as the cutting starting surface and taking the second principal surface thereof as the cutting ending surface. As shown in FIG. 8, an area of the first principal surface side of the semiconductor light emitting device is smaller than that of the second principal surface side thereof, and the side surfaces (cut sections) of the semiconductor light emitting device in the direction perpendicular to the first principal surface have the taper shape.

Moreover, FIG. 9 shows an example of the semiconductor light emitting device manufactured by the method described with reference to FIG. 7(a) to FIG. 7(d), that is, while taking the second principal surface of the wafer 20 as the cutting starting surface and taking the first principal surface thereof as the cutting ending surface. As shown in FIG. 9, the area of the first principal surface side of the semiconductor light emitting device is larger than that of the second principal surface side thereof, and the side surfaces (cut surfaces) of the semiconductor light emitting device in the direction perpendicular to the first principal surface have the taper shape.

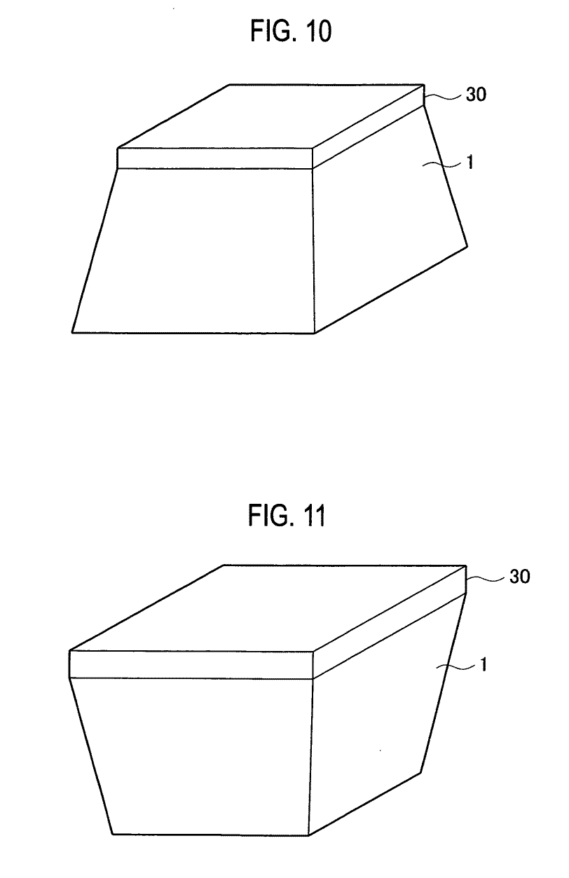

Note that, though the taper shape of the side surfaces is curved in each of the examples shown in FIG. 8 and FIG. 9, the taper shape may be formed so as to be straight. FIG. 10 shows an example of a semiconductor light emitting device manufactured so that the taper shape of the side surfaces is straight while taking the first principal surface of the wafer 20 as the cutting starting surface and taking the second principal surface thereof as the cutting ending surface. Moreover, FIG. 11 shows an example of a semiconductor light emitting device manufactured so that the taper shape of the side surfaces is straight while taking the second principal surface of the wafer 20 as the cutting starting surface and taking the first principal surface thereof as the cutting ending surface.

### Examples

Comparisons in characteristics and shapes among the semiconductor light emitting devices manufactured by the respective methods described above will be shown below. The respective methods are: the wafer cutting method described with reference to FIG. 5(a) to FIG. 5(c), that is, the method of cutting the wafer by means of the dicer having one blade (hereinafter, referred to as “full cut cutting”); the wafer cutting method described with reference to FIG. 6(a) to FIG. 6(d), that is, the method of cutting the wafer from the first principal surface to the second principal surface by means of the dicer using two blades different in blade thickness from each other (hereinafter, referred to as “first taper type cutting”); the wafer cutting method described with reference to FIG. 7(a) to FIG. 7(d), that is, the method of cutting the wafer from the second principal surface to the first principal surface by means of the dicer using two blades different in blade thickness from each other (hereinafter, referred to as “second taper type cutting”); and the method of breaking the wafer into the respective chips (hereinafter, referred to as “scriber cutting”).

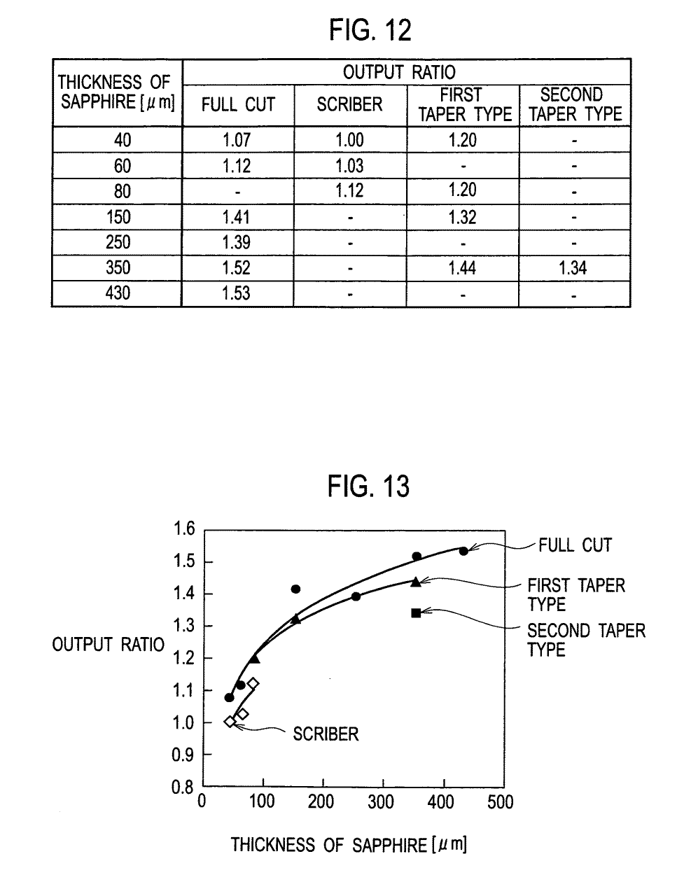

FIG. 12 shows a table in which chip thicknesses of the semiconductor light emitting elements and outputs of the light emitted therefrom are compared with one another, the semiconductor light emitting elements being manufactured by the respective methods, which are: the “full cut cutting”; the “first taper type cutting”; the “second taper type cutting” and the “scriber cutting”. Columns of “thickness of sapphire” in FIG. 12 indicate the thicknesses of the transparent substrates made of the sapphire, and columns of “output ratio” indicate the outputs of the semiconductor light emitting elements in the case where the output of the semiconductor light emitting device is taken as 1 when the wafer in which the sapphire thickness is 40 μm is cut by means of a scriber.

FIG. 13 shows results of making a graph of the characteristics shown in FIG. 12. In FIG. 13, black circle marks indicate data of the “full cut cutting”, black triangle marks indicate data of the “first taper type cutting”, black square marks indicate data of the “second taper type cutting”, and rhombus marks indicate data of the “scriber cutting”.

As shown in FIG. 12 and FIG. 13, no matter which the cutting method may be, the output is increased when the sapphire thickness is thickened. It is preferable that the sapphire thickness be 60 μm or more, and be approximately 350 μm in order to obtain a large output. An upper limit of the sapphire thickness that can accept the “scriber cutting” is approximately 80 μm. Accordingly, each method of fully cutting the wafer by means of the blade, which has been described with reference to FIG. 5 to FIG. 7, is advantageous in comparison with the method of breaking the wafer into the respective chips.

Moreover, from FIG. 12 and FIG. 13, it is understood that, in the case where the sapphire thicknesses are equivalent to one another, a larger output is obtained by each method of fully cutting the wafer by means of the blade in comparison with the method of breaking the wafer into the respective chips. This is because the side surfaces of each semiconductor light emitting device obtained by fully cutting the wafer by means of the blade are rough surfaces, and because the side surfaces of each semiconductor light emitting device obtained by breaking the wafer into the respective chips are mirror surfaces. In other words, the wafer is fully cut by means of the dicer, whereby the irregularities caused by cutting the wafer in the dicing process are generated on the side surfaces of the transparent substrate 1, and the side surfaces become the rough surfaces as shown in FIG. 2(b). Therefore, the light that is generated in the active layer 3 of the semiconductor light emitting element and is incident onto the transparent substrate 1 is not reflected by the side surfaces of the transparent substrate 1, but is likely to be outputted from the side surfaces to the outside, whereby the output is enhanced.

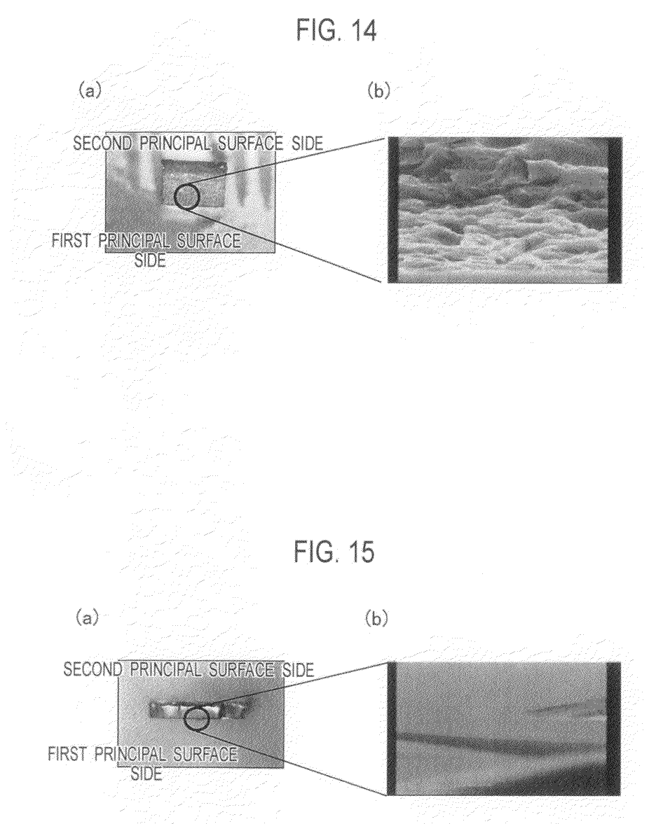

FIG. 14(a) shows a cut section of the chip in the case where the wafer with the sapphire thickness of 350 μm is cut by the “full cut cutting”. FIG. 14(b) is an SEM photograph in which a part of FIG. 14(a) is enlarged (by approximately 6000 times).

FIG. 15(a) shows a cut section of the chip in the case where the wafer with the sapphire thickness of 80 μm is cut by the “scriber cutting”. As shown in FIG. 15(a), though there are irregularities on cut sections of a groove formed as a scribe line on a surface thereof, irregularities on cut sections of deeper portions than the groove concerned are small, and the cut sections concerned become mirror surfaces. FIG. 15(b) is an SEM photograph in which a part of one of the mirror surfaces of FIG. 15(a) is enlarged (by approximately 6000 times).

As shown in FIG. 14(b) and FIG. 15(b), while the cut section of the chip, which is obtained by the “scriber cutting”, is a smooth mirror surface for the most part, the cut section of the chip, which is obtained by the “full cut cutting”, is entirely a rough surface. Therefore, in the case of the “scriber cutting”, the light that is generated in the active layer of the semiconductor light emitting element and is incident onto the sapphire substrate is reflected by the cut sections of the chip, and is less likely to be outputted from the sapphire substrate; however, in the case of the “full cut cutting”, since the cut sections of the chip are the rough surfaces, the light incident onto the sapphire substrate is outputted to the outside from the side surfaces (cut sections) of the chip, whereby the output is increased. Roughness of the cut sections of the chip can be adjusted by adjusting the particle diameter of the diamonds arranged on the blade surface.

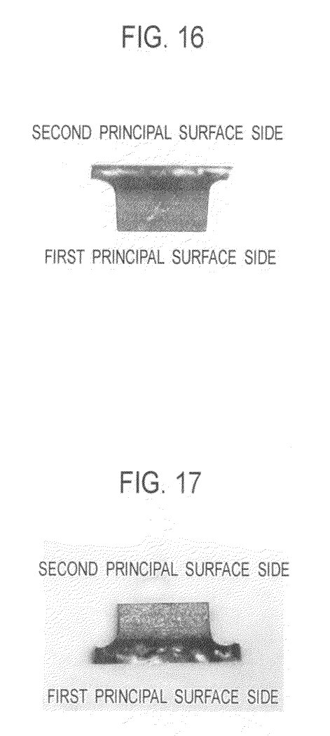

FIG. 16 shows a cut section of the chip in the case where the wafer with the sapphire thickness of 350 μm is cut by the “first taper type cutting”. As shown in FIG. 16, in accordance with the “first taper type cutting”, a chip width is widened in the second principal surface side more than in the first principal surface side.

FIG. 17 shows a cut section of the chip in the case where the wafer with the sapphire thickness of 350 μm is cut by the “second taper type cutting”. As shown in FIG. 17, in accordance with the “second taper type cutting”, the chip width is widened in the first principal surface side more than in the second principal surface side.

As described above, in the semiconductor light emitting device according to the first embodiment of the present invention, the wafer is fully cut by means of the dicer, whereby the side surfaces of the transparent substrate 1 become the rough surfaces as shown in FIG. 2(b) because of the irregularities caused by cutting the wafer in the dicing process. Therefore, in the semiconductor light emitting device shown in FIG. 1, the light that is generated in the active layer 3 of the nitride semiconductor layer 30 formed on the transparent substrate 1 and is incident onto the transparent substrate 1 is not reflected by the side surfaces of the transparent substrate 1, but is likely to be outputted therefrom to the outside, whereby the light can be outputted efficiently. Moreover, in accordance with the manufacturing method according to the first embodiment of the present invention, in the case of manufacturing the semiconductor light emitting device by dividing the wafer 20 into the chips, the occurrence of the cracks in the cut parts can be suppressed.

### Second Embodiment

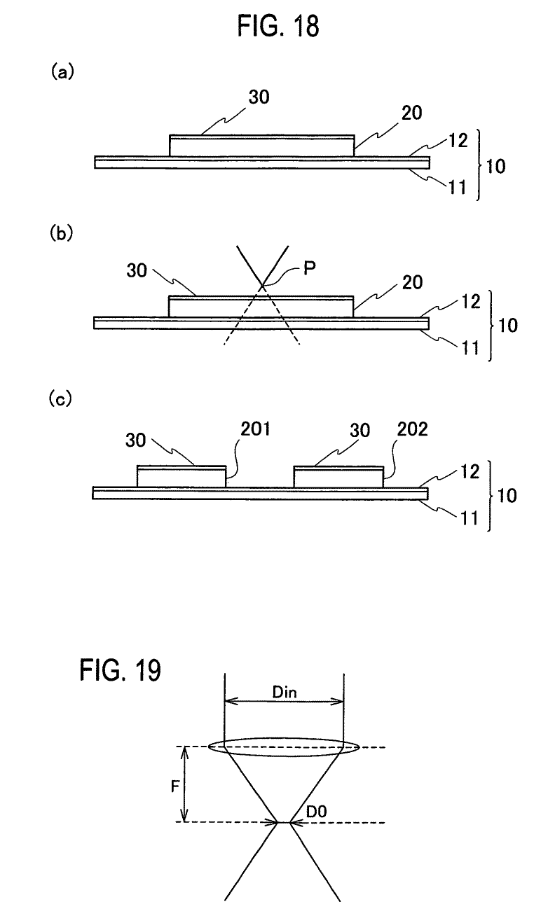

With reference to FIG. 18(a) to FIG. 18(c), a description will be made of a method for manufacturing the semiconductor light emitting device according to a second embodiment of the present invention in such a manner that the wafer 20 is cut from the first principal surface toward the second principal surface by using a laser as the cutting apparatus. In other words, the manufacturing method according to the second embodiment is different in using the laser as the cutting apparatus from the manufacturing method according to the first embodiment, which uses, as the cutting apparatus, the dicer including the blade. Here, a description will be made of an example where the wafer 20 is cut into the plurality of chips while taking the first principal surface as the cutting starting surface and taking the second principal surface as the cutting ending surface. Note that, as will be described later, the wafer 20 can also be cut while taking the second principal surface as the cutting starting surface and taking the first principal surface as the cutting ending surface.

First, as shown in FIG. 18(a), the second principal surface of the wafer 20 as the subject to be divided, in which the nitride semiconductor layer 30 is formed on the first principal surface, is pasted onto the adhesive. 12 side of the adhesive tape 10 composed by stacking the tape base material 11 and the adhesive 12 on each other.

Next, as shown in FIG. 18(b), a focus of the laser is set on a midpoint P between the laser and an either surface of the first principal surface and the second principal surface, which is closer to the laser, that is, the first principal surface from which the cutting is started. Hereinafter, a value of a distance between the midpoint P and the first principal surface will be referred to as a “defocus value”. There is a correlation between the defocus value and a width (kerf width) of a groove formed by etching the wafer 20 by means of a laser beam, and the defocus value is set so that the kerf width can be a desired value. A setting value of the defocus value will be described later.

Subsequently, as shown in FIG. 18(c), the wafer 20 is fully cut from the first principal surface to the second principal surface by means of the beam outputted from the laser in which the focus is set as described with reference to FIG. 18(b), and the chip 201 and the chip 202, in each of which the nitride semiconductor layer 30 is formed, are obtained.

As shown in FIG. 19, in the case where a beam width at the focus of the laser is D0, an incident beam diameter is Din, and a focal length is F, then the beam width D0 is represented by the following Expression (1):

D0=4×F×λ/(n×Din) (1)

In Expression (1), A is a laser wavelength. As the laser, an yttrium-aluminum-garnet (YAG) laser with a laser wavelength λ of 532 nm, and the like are adoptable; however, the laser wavelength A may be 266 nm or 355 nm.

For example, in the case where specifications of the laser are that F is equal to 1.5 cm, λ is equal to 532 nm, and Din is equal to 5.98 μm, then the beam width D0 is equal to 5.98 μm. Specifically, the beam width at the focus is approximately 6 μm theoretically, and in the case where the focus of the laser is set on the first principal surface, then the kerf width also is approximately 6 μm in a similar way.

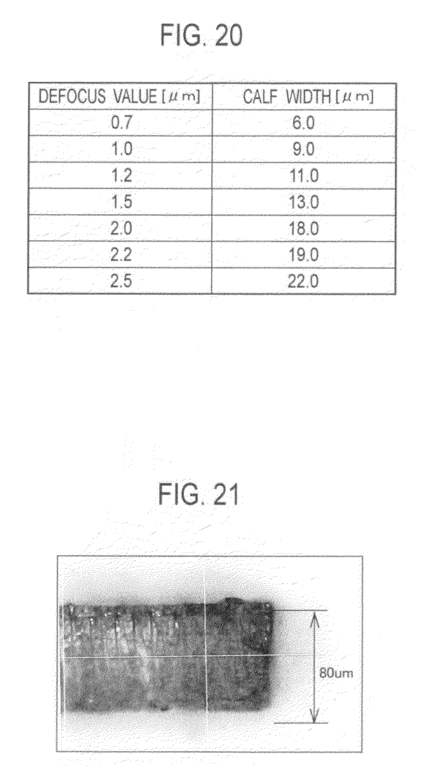

FIG. 20 shows relationships between the defocus values and the kerf widths in the laser having the above-described specifications. As shown in FIG. 20, for example, in the case of setting the defocus value at 1 μm, the kerf width is 9 μm.

In usual, objects (debris) generated in the event of cutting the wafer by means of the laser are adhered onto the side surfaces of the groove that is being cut. In the case where the kerf width is narrow, then the debris fill the groove, sometimes making it difficult to cut the wafer. Therefore, in order that the kerf width can be enough to prevent the groove from being filled with the debris, it is preferable to set the defocus value so that the kerf width is, for example, approximately 10 μm.

FIG. 21 shows a cut section of a chip with the thickness of 80 μm, which is cut by the method described above. As shown in FIG. 21, irregularities caused by cutting the wafer by means of the laser are generated on the entire cut section of the chip.

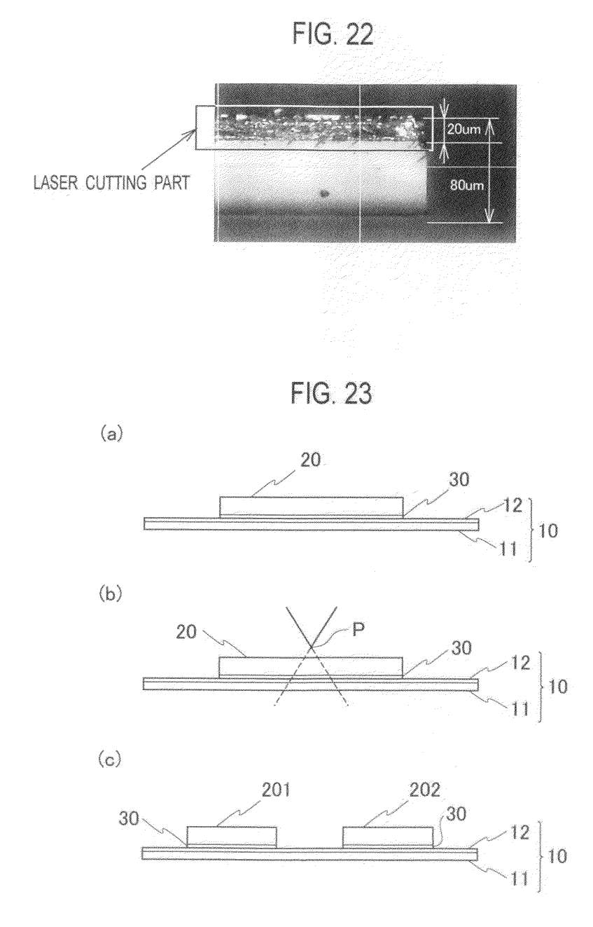

For comparison, FIG. 22 shows a cut section of a chip in the case where the wafer is broken into the chips after the subscribe lines are formed. FIG. 22 is an example where a chip with the thickness of 80 μm is cut out after a groove is formed to a depth of 20 μm by means of the laser. As shown in FIG. 22, there are irregularities on the cut section of the groove formed by means of the laser; however, irregularities on a cut section of a deeper portion than the groove concerned are small, and the cut section is a mirror surface.

In the above, the description has been made of the example of fully cutting the wafer 20 from the first principal surface to the second principal surface by means of the laser. However, it is a matter of course that the wafer 20 may be fully cut from the second principal surface to the first principal surface by means of the laser. In this case, an appropriate defocus value is set so as to obtain a desired kerf width, and the focus of the laser is set between the laser and the second principal surface that is the cutting starting surface. A specific method of this will be described below with reference to FIG. 23(a) to FIG. 23(c).

First, as shown in FIG. 23(a), the first principal surface of the wafer 20 is pasted onto the adhesive 12 side of the adhesive tape 10.

Next, as shown in FIG. 23(b), the focus of the laser is set on the midpoint P between the laser and the second principal surface from which the cutting is started. The defocus value as the distance between the midpoint P and the second principal surface is set so that the kerf width can be a desired value.

Subsequently, as shown in FIG. 23(c), the wafer 20 is fully cut from the second principal surface to the first principal surface by means of the beam outputted from the laser in which the focus is set as described with reference to FIG. 23(b), and the chip 201 and the chip 202, in each of which the nitride semiconductor layer 30 is formed, are obtained.

In accordance with the method for manufacturing the semiconductor light emitting device according to the second embodiment of the present invention, which has been described above, the wafer 20 can be divided by being fully cut. Therefore, unlike the method of breaking the wafer into the respective chips after forming the scribe lines, the occurrence of the cracks in the vicinities of the cut parts can be suppressed, and the shapes of the chip surfaces do not vary. Accordingly, the yield of the semiconductor light emitting device can be enhanced.

Moreover, though it is necessary to set the thickness of the wafer at approximately 100 μm, for example, 80 μm in the method of breaking the wafer into the respective chips, the wafer 20 can be fully cut even if the thickness thereof is approximately 350 μm in accordance with the method for manufacturing the semiconductor light emitting device according to the second embodiment of the present invention. Therefore, the step of thinning the wafer 20 can be omitted. Moreover, since it is unnecessary to apply the impact for breaking the wafer into the chips, the manufacturing process can be shortened.

As described above, in accordance with the method for manufacturing the semiconductor light emitting device according to the second embodiment of the present invention, the wafer is fully cut by means of the laser, whereby the semiconductor light emitting device capable of efficiently outputting the light that is generated in the active layer 3 of the semiconductor light emitting element and is incident onto the transparent substrate 1 can be formed by dividing the wafer 20 while suppressing the occurrence of the cracks in the cut parts.

### Other Embodiments

The description has been made as above of the present invention on the basis of the first and second embodiments; however, it should not be understood that the description and the drawings, which form a part of the disclosure, limit this invention. From this disclosure, a variety of alternative embodiments, examples and operation technologies will be obvious for those skilled in the art.

In the already made description of the embodiments, the example has been illustrated, where the semiconductor light emitting element has the quantum well structure in which the active layer 3 is sandwiched by the n-type semiconductor layer 2 and the p-type semiconductor layer 4; however, the light emitting element may have other structures such as a pn junction in which the n-type semiconductor layer and the p-type semiconductor layer are directly bonded to each other. Moreover, though the example where the nitride semiconductor is stacked on the sapphire substrate has been illustrated, the above-described scribing method can be applied also in the case where the wafer is less likely to be broken even if the semiconductor light emitting element has other semiconductor layers and structures.

As described above, it is a matter of course that the present invention incorporates a variety of embodiments and the like, which are not described herein. Hence, the technical scope of the present invention should be determined only by the invention specifying items according to the scope of claims reasonable based on the above description.

### INDUSTRIAL APPLICABILITY

The semiconductor light emitting device of the present invention and the method for manufacturing the same are usable for the semiconductor industry and the electronic instrument industry, which incorporate the manufacturing industry of manufacturing a light emitting device including a semiconductor layer arranged on a semiconductor substrate.

1. A semiconductor light emitting device comprising:
a transparent substrate including a first principal surface and a second principal surface opposite with the first principal surface, in which side surfaces between the first principal surface and the second principal surface are rough surfaces; and
a semiconductor light emitting element arranged on the first principal surface of the transparent substrate and composed by stacking nitride semiconductors on each other.

2. The semiconductor light emitting device of claim 1, wherein the semiconductor light emitting element has a structure in which an n-type semiconductor layer, an active layer and a p-type semiconductor layer are stacked on one another in this order.

3. The semiconductor light emitting device of claim 1, wherein a thickness of the transparent substrate is 40 μm or more to 700 μm or less.

4. The semiconductor light emitting device of claim 1, wherein the first principal surface and the second principal surface are different in area from each other,, and cut sections of the transparent substrate in a direction perpendicular to the first principal surface have a taper shape.

5. The semiconductor light emitting device of claim 1, wherein the side surfaces are rough surfaces because of irregularities caused by cutting the transparent substrate by a dicing process.

6. A method for manufacturing a semiconductor light emitting device, in which a wafer that is made of sapphire and includes a first principal surface and a second principal surface opposite with the first principal surface, the first principal surface having a nitride semiconductor layer formed thereon, is divided into a plurality of chips, the method comprising:
preparing a cutting apparatus;
pasting the wafer onto an adhesive tape; and
cutting the wafer from one of the first principal surface and the second principal surface to the other by means of the cutting apparatus until the wafer is divided into the plurality of chips.

7. The method for manufacturing the semiconductor light emitting device of claim 6, wherein the cutting apparatus is a laser, and in cutting the wafer, a focus of the laser is set on a midpoint between the laser and an either surface of the first principal surface and the second principal surface, the surface being closer to the laser, and the wafer is cut from the surface closer to the laser to the surface opposite with the surface closer to the laser by means of a beam outputted from the laser in which the focus is set.

8. The method for manufacturing the semiconductor light emitting device of claim 7, wherein a wavelength of the laser is any of 532 nm, 266 nm and 355 nm.

9. The method for manufacturing the semiconductor light emitting device of claim 6, wherein the cutting apparatus includes a blade, and in cutting the wafer, the wafer is cut from one of the first principal surface and the second principal surface to the other by means of the blade.

10. The method for manufacturing the semiconductor light emitting device of claim 9, wherein the blade is resin and metal blades in which a plurality of diamonds is arranged in resin and metal.

11. The method for manufacturing the semiconductor light emitting device of claim 6, wherein the cutting apparatus includes a first blade and a second blade thinner in blade thickness than the first blade, and in cutting the wafer, a groove is formed from one of the first principal surface and the second principal surface to a midpoint of an inside of the wafer by means of the first blade, and a groove is formed from the midpoint to the other of the first principal surface and the second principal surface by means of the second blade, whereby the wafer is cut.

12. The method for manufacturing the semiconductor light emitting device of claim 11, wherein the first and second blades are resin and metal blades in which a plurality of diamonds is arranged in resin and metal.
